(19) United States
(12) Patent Application Publication
(10) Pub. No.: US 2024/0384164 A1
(43) Pub. Date: Nov. 21, 2024

(54) HYDROPHILIC QUANTUM DOT, HYDROPHILIC SOLVENT-TYPE QUANTUM INK COMPOSITION INCLUDING THE SAME, AND LIGHT-EMITTING DEVICE AND DISPLAY INCLUDING THE SAME

(71) Applicants: SAMSUNG ELECTRONICS CO., LTD., Suwon-si (KR); HANSOL CHEMICAL CO., LTD, Seoul (KR)

(72) Inventors: Yeseul PARK, Suwon-si (KR); Somang KIM, Seoul (KR); Dohyeong KIM, Seoul (KR); Jaehong NOH, Seoul (KR); Sanghyun SOHN, Suwon-si (KR); Daehee LEE, Suwon-si (KR); Kyunghye KIM, Seoul (KR); Taehun PARK, Seoul (KR); Sujin LEE, Seoul (KR)

(21) Appl. No.: 18/664,873

(22) Filed: May 15, 2024

(30) Foreign Application Priority Data
May 15, 2023 (KR) 10-2023-0062699

(51) Int. Cl. C09K 11/06; C09D 11/328; H10K 50/115; H10K 85/30

(52) U.S. Cl. CPC C09K 11/06; C09D 11/328; H10K 50/115; H10K 85/381; C09K 2211/183

(57) ABSTRACT

The disclosure relates to hydrophilic quantum dots, a hydrophilic solvent-type quantum dot ink composition including the same, and a light-emitting device and a display that are manufactured by including the same, and more particularly, to hydrophilic quantum dots that are dispersible in a polar solvent with high viscosity, allowing for easy control of viscosity, a hydrophilic solvent-type quantum dot ink composition including the same, and a light-emitting device and a display that include the same.

### CROSS-REFERENCE TO RELATED APPLICATION

This application is based on and claims priority under 35 U.S.C. § 119 to Korean Patent Application No. 10-2023-0062699, filed on May 15, 2023, in the Korean Intellectual Property Office, the disclosure of which is incorporated by reference herein in its entirety.

### BACKGROUND

### 1. Field

The disclosure relates to hydrophilic quantum dots, a hydrophilic solvent-type quantum dot ink composition including the same, and a light-emitting device and a display that are manufactured by including the same.

### 2. Description of the Related Art

Quantum dots (QDs), known as semiconductor nanocrystals, can produce various colors by generating light of different wavelengths depending on particle size without a change in material type. Due to higher color purity and better optical stability than existing light-emitting materials, QDs are attracting attention as next-generation materials for light-emitting devices.

In the display field, QDs are typically dispersed in a polymer matrix, and in the form of complexes, can be applied to various displays, electronic devices, or in addition to TVs and LEDs.

Materials for color filters require high sensitivity, strong adhesion to a substrate, chemical resistance, heat resistance, and the like. Regarding the manufacture of color filters applied to displays in the art, in general, a desired pattern is formed first through an exposure process using a photomask by using a photosensitive resist composition, and subsequently, a color filter is prepared by a patterning process in which unexposed areas of the formed pattern are dissolved and removed by a development process. However, this manufacturing process was accompanied by problems including rising costs due to wasted materials.

Recently, in order to address the upgrade of materials used in pixels and the consequent cost increase, interest has been drawn to minimizing the use of materials as much as possible by using materials only in desired areas, rather than performing patterning using conventional spin-coating or slit-coating. The most representative method is an inkjet method, which includes a bubble jet method and a piezoelectric method. In the inkjet method, materials are used only for desired pixels, and thus unnecessary waste of materials may be prevented.

### SUMMARY

Provided are a hydrophilic quantum dot and a hydrophilic solvent-type quantum dot ink composition that can be inkjet printed by modifying the surface of quantum dots and inducing them to be dispersed in polar solvents with high viscosity.

Also provided are hydrophilic quantum dots that are dispersible in a polar solvent with high viscosity, allowing for easy control of viscosity, a hydrophilic solvent-type quantum dot ink composition including the same, and a light-emitting device and a display that include the same.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 shows results of an experimental example 4 for an ink composition of the example 4;

FIG. 2 shows results of an experimental example 4 for an ink composition of example 4-a;

FIG. 3 shows results of an experimental example 4 for an ink composition of example 4-b;

FIG. 4 shows results of an experimental example 5;

FIG. 5 shows results of an experimental example 6;

FIG. 6 illustrates a light-emitting device of a display apparatus in accordance with embodiments.

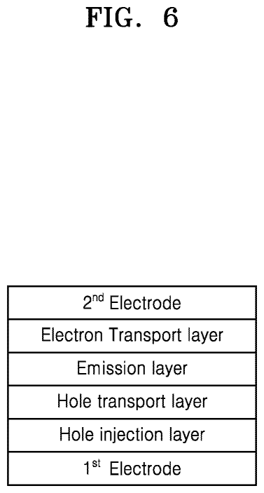

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

All terms (including technical and scientific terms) used in the present specification, unless otherwise defined, may be used with meanings that can be commonly understood by those skilled in the art to which the present invention pertains. In addition, terms defined in commonly used dictionaries are not to be interpreted ideally or excessively unless clearly specifically defined.

The term “organic group” as used in the present specification refers to a linear or branched C1-C10 alkyl group, a linear or branched C2-C10 alkenyl group, or a linear or branched C2-C10 alkynyl group. Here, the alkyl group, the alkenyl group, and the alkynyl group may each be substituted or unsubstituted.

The term “alkyl” as used in the present specification refers to a monovalent substituent derived from a linear or branched C1-C10 saturated hydrocarbon. The term “alkylene group” as used herein refers to a divalent group having the same structure as the alkyl group derived from a linear or branched saturated hydrocarbon having 1 to 40 carbon atoms

Examples thereof may include methyl, ethyl, propyl, isobutyl, sec-butyl, pentyl, iso-amyl, hexyl, and the like, but are not limited thereto. The term “alkenyl” as used in the present specification refers to a monovalent substituent derived from a linear or branched C2-C10 unsaturated hydrocarbon having one or more carbon-carbon double bonds. The term “alkenylene group” as used herein refers to a divalent group having the same structure as the alkenyl group derived from a linear or branched unsaturated hydrocarbon that has at least one carbon-carbon double bond and 2 to 40 carbon atoms.

Examples thereof may include vinyl, allyl, isopropenyl, 2-butenyl, and the like, but are not limited thereto. The term “alkynyl” as used in the present specification refers to a monovalent substituent derived from a linear or branched C2-C10 unsaturated hydrocarbon having one or more carbon-carbon triple bonds.

Examples thereof may include ethyny, n-propynyl, n-but-2-enyl, n-hex-3-enyl, and the like, but are not limited thereto.

### Hydrophilic Solvent-type Quantum Dot Ink Composition

A quantum dot composition used in an inkjet method is required to have a viscosity of 100 cps or less, preferably, 50 cps or less, and thus achieving a low viscosity is essential. Non-solvent type ink is difficult to use in development of self-emissive ELQD ink materials, so that solvent-type ink is in progress. However, there are technical limitations in that viscosity control is difficult with non-polar solvents used in solvent-type ink and dispersibility is poor in polar solvents, and related research is also insufficient.

In this regard, a prior invention relating to a quantum dot microcapsule ink that has a charge which can be dispersed in resins and binders while achieving a low viscosity of 10 cps or less has been disclosed (10-2340892, published on Dec. 17, 2021). However, additional processes were required, such as triboelectric charging to make a shell region of the quantum dot capsule positively or negatively charged, coating the capsule surface with a charge control agent, etc.

In addition, in the case of a quantum dot-containing emission layer to be used in self-emissive displays for inkjet printing, solvent types are not clear so that various solvent types are being studied and developed. When a non-polar solvent-type emission layer is used, for example, when a non-polar solvent-type electron transport layer-forming ink composition of the same nature is used, there is a technical problem in that the emission layer is etched. Therefore, there is a need for hydrophilic quantum dots and hydrophilic solvent-type quantum dot ink compositions that can be dispersed in polar solvents.

A quantum dot ink composition according to an embodiment of the disclosure is an ink composition that may form an emission layer when ejected by inkjet printing, roll-to-roll coating, screening printing, spray coating, dip coating, or spin coating. The quantum dot ink composition according to an embodiment may include hydrophilic quantum dots, which are defined as having been surface modified with a ligand, and a polar solvent, wherein the hydrophilic quantum dots may be dispersed in the polar solvent.

Hereinafter, the composition of the quantum dot ink composition will be described in detail as follows.

### Quantum Dots

Quantum dots (QDs) are nano-sized semiconductor materials that may have different energy bandgaps depending on size and composition, and thus may emit light of various emission wavelengths.

Such QDs may have: a homogeneous single-layer structure; a multi-layer structure in a core-shell form, a gradient form; or a mixed structure thereof. In the core-shell form, the shell may have multiple layers (e.g., core/shell/shell), and in this case, each layer may include different ingredients, such as one or more metal oxides or one or more metalloid oxides.

The QDs may be freely selected from Group II-VI compounds, Group III-V compounds, Group IV-VI compound, Group IV elements, Group IV compounds, and a combination thereof. When the QDs are in the core-shell form, the core and the shell may each be freely composed of ingredients exemplified below.

In an embodiment, the Group II-VI compound may be selected from the group consisting of: binary compounds selected from the group consisting of CdO, CdS, CdSe, CdTe, ZnO, ZnS, ZnSe, ZnTe, HgS, HgSe, HgTe, MgSe, MgS, and mixtures thereof; ternary compounds selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and quaternary compounds selected from the group consisting of CdZnSeS, CdZnSeTe, CdZnSTe, CdHgSeS, CdHgSeTe, CdHgSTe, HgZnSeS, HgZnSeTe, HgZnSTe, and mixtures thereof.

In one or more embodiments, the Group III-V compound may be selected from the group consisting of: binary compounds selected from GaN, GaP, GaAs, GaSb, AlN, AlP, AlAs, AlSb, InN, InP, InAs, InSb, and mixtures thereof; ternary compounds selected from the group consisting of GaNP, GaNAs, GaNSb, GaPAs, GaPSb, AlNP, AlNAs, AlNSb, AlPAs, AlPSb, InNP, InNAs, InNSb, InPAs, InPSb, and mixtures thereof; and quaternary compounds selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the Group IV-VI compound may be selected from the group consisting of: binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and quaternary compounds selected from the group consisting of SnPbSSe, SnPbSeTe, SnPbSTe, and mixtures thereof.

In one or more embodiments, the Group IV element may be selected from the group consisting of Si, Ge, and mixtures thereof. In one or more embodiments, the Group IV compound may be selected from the group consisting of SiC, SiGe, and mixtures thereof.

In one or more embodiments, an alloy-type compound may be a ternary compound selected from InZnP and the like.

The surface of the QD may include divalent to tetravalent metals. For example, as the divalent to tetravalent metals, Mg, Ca, Sc, Ti, V, Cr, Mn, Fe, Co, Ni, Cu, Zn, Ga, Ge, Sr, Y, Zr, Nb, Mo, Tc, Ru, Rh, Pd, Cd, In, or Sn may be included. Before surface modification, additional metals forming the surface of the DQ may be added to expand areas where ligands may attach, thereby effectively modifying the surface of the QDs.

The aforementioned binary compounds, the ternary compounds, or the quaternary compounds may exist in particles at a uniform concentration, or may exist in the same particles in a state in which a concentration distribution is partially different. In addition, the QDs may have a core/shell structure in which a single QD surrounds other QDs. The interface between the core and the shell may have a concentration gradient in which the concentration of an element existing in the shell decreases toward the center of the core.

The form of the QDs is not particularly limited as long as it is a form commonly used in the art. In an embodiment, rod-shaped, pyramid-shaped, disc-shaped, multi-armed, or cubic nanoparticles, nanotubes, nanowires, nanofibers, or nanoplate particle may be used.

In addition, the size of the QDs is not particularly limited, and may be appropriately adjusted within ranges known in the art. In an embodiment, the average particle diameter (D50) of the QD may be in a range of about 2 nm to about 10 nm. As such, when the particle diameter of the QDs is controlled to be in a range of about 2 nm to about 10 nm, light of a desired color may be emitted. For example, when the particle diameter of the QDs in the form of a core/shell structure containing InP is in a range of about 5 nm to about 6 nm, light with a wavelength of about 520 nm to about 550 nm may be emitted. When the particle diameter of the QDs in the form of a core/shell structure containing InP is in a range of about 7 nm to about 8 nm, light with a wavelength of about 620 nm to about 640 nm may be emitted. For example, as the QDs emitting blue light, non-cadmium (Cd)-based Group III-V QDs (e.g., InP, InGaP, InZnP, GaN, GaAs, GaP, etc.) may be used.

In addition, the QDs may have a full width at half maximum (FWHM) of about 40 nm or less of an emission wavelength spectrum, and within this range, the color purity or reproducibility of the QDs may be improved. In addition, since light emitted through the QDs may be emitted in all directions, the wide viewing angle of the QDs may be improved.

To the surface of the QDs, an organic ligand consisting of oleic acid, myristic acid, lauric acid, palmitic acid, stearic acid, oleyl amine, n-octyl amine, hexadecyl amine, hexyl phosphonic acid, n-octyl phosphonic acid, tetradecyl phosphonic acid, octadecyl phosphonic acid, a combination thereof, and the like may be attached. Examples of the organic ligand include functional groups such as a carboxylic acid, an acrylate, a pyridine, a thiol, a phosphine, a phosphine oxide, a primary amine, a secondary amine, a combination thereof, and the like. The organic ligand may include a hydrophobic moiety where the hydrophobic moiety refers to parts of the organic ligand with non-polar functional groups such as hydrocarbon groups. The hydrophobic moiety may be a linear or branched C1-C30 alkyl group, a linear or branched C2-C30 alkenyl group, or a linear or branched C2-C30 alkynyl group, and more specifically, may be a linear or branched C5-C30 alkyl group, a linear or branched C5-C30 alkenyl group, or a linear or branched C5-C30 alkynyl group.

According to an embodiment of the disclosure, the amount of the QDs may be, depending on the characteristics of the QDs, in a range of about 1 wt % to about 20 wt %, preferably, about 1 wt % to about 10 wt %, more preferably, about 1 wt % to about 5 wt %, based on the total weight of the QDs.

A metal for forming the surface of the QDs may be added to a QD solution, and the amount of the added metal may be, based on the total weight of the QD composition, in a range of about 1 wt % to about 20 wt %, preferably, about 1 wt % to about 10 wt %, more preferably, about 1 wt % to about 5 wt %. For example, when the surface of the QD includes a metal, Zn, ZnCl₂ may be added.

In addition, the weight ratio of QDs to a metal compound, which is added to the QDs and forms the surface of the QDs, may be in a range of about 3:1 to about 1:3, preferably, about 2:1 to about 1:2, more preferably, about 1:1.

### Ligand

In the QD composition according to the disclosure, a ligand may serve to modify the surface of the QDs. Due to the hydrophobic surface characteristics of the QDs, the QDs have barriers to dispersion in hydrophilic solvents or polar solvents. Thus, by modifying the surface of the QDs with an appropriate ligand, the miscibility of the QDs in hydrophilic solvents may be improved and the viscosity of the QDs may be adjusted for use in inkjet printing.

According to an embodiment of the disclosure, the ligand may include a reactive group capable of binding to the surface of the QDs and an organic group having hydrophilicity. Preferably, the ligand may include a reactive group capable of binding to the surface of the QDs on one side and an organic group having hydrophilicity on the other side. More preferably, the ligand may include one or more reactive groups capable of binding to the surface of the QDs on one side and one or more organic ligands having hydrophilicity at the end portion.

Non-limiting examples of a functional group capable of binding to the surface of the QDs may be selected from the group consisting of —COOH, —CN, NH₂, NH, N, SH, PO, P, OH, COOR′ (where R′ is an alkyl group), —C(═O)—, PO(OH)₂, POOH, and a combination thereof.

The organic ligand having hydrophilicity in the ligand may be an organic group having 3 to 10 carbon atoms, and preferably may include one or more elements selected from the group consisting of nitrogen (N), oxygen (O), and sulfur (S), and more specifically, may include a carboxy group, a hydroxy group, a sulfur group, a sulfonyl group, an ammonium group, an amine group, ethylene glycol, polyethylene glycol (PEG), etc.

As a part of the ligand, the organic ligand having hydrophilicity in the ligand may be included therein in the form of 1 to 20 independently selected moieties.

As an example of the ligand, a bifunctional molecule including a thiol group and an organic group that includes carboxylic acid, and examples thereof may include, although not limited thereto, 3-mercaptopropionic acid, 6-mercaptohexanoic acid, 7-mercaptoheptanoic acid, 8-mercaptooctanoic acid, 12-mercaptododecanoic acid, mercaptosuccinic acid, or dimercaptosuccinic acid.

According to an embodiment of the disclosure, the amount of the ligand may be, depending on the characteristics of the QDs, in a range of about 1 wt % to about 40 wt %, preferably, about 1 wt % to about 20 wt %, more preferably, about 1 wt % to about 10 wt %, based on the total weight of the QDs.

In addition, the weight ratio of the QDs to the ligand may be in a range of about 1:1 to about 1:5, preferably, about 1:1 to about 1:3, more preferably, about 1:1.5 to about 1:2.5.

### Polar Solvent

Polar solvent with high viscosity have excellent properties for preparing ink compositions suitable for use in inkjet printing methods, but may have problems in uniformly dispersing QDs.

According to an embodiment of the disclosure, the polar solvent may include two or more types, preferably propylene glycol. More preferably, the polar solvent may further include one or more solvent including one or more selected from the group consisting of a carboxy group, a hydroxy group, a sulfo group, an ester group, and a ketone group. Here, a volume ratio of propylene glycol to the remaining polar solvent may be in a range of about 1:0.5 to about 1:5, preferably about 1:1 to about 1:3. The optimum volume ratio may vary depending on the physical properties of the remaining polar solvent added.

The QD ink composition according to the disclosure may have a viscosity in a range of about 2 centipoise (cps) to about 20 cps, preferably about 2 cps to about 16 cps, more preferably about 2.1 cps to about 15 cps. Within these ranges, the QD ink composition may be suitable for use in an ink printing method.

In addition, the QD ink composition according to the disclosure may have a non-dimensional roughness in a range of about 0.5 nm to about 5 nm, preferably about 1 nm to about 3 nm, more preferably, about 1 nm to about 2 nm. The more uniform the non-dimensional roughness after thinning, the more uniform a thin film may be realized when applied to a light-emitting device and a display apparatus. In this regard, a uniform color reproduction rate may be resulted, and when driving devices, leakage does not occur, thereby improving driving characteristics of the devices.

### <Light-emitting Device and Display Apparatus>

A light-emitting device according to an embodiment of the disclosure is distinguished from a light-emitting device in the art in that an emission layer formed by the aforementioned QD ink composition is included.

A light-emitting device according to an embodiment of the disclosure may be a QD light-emitting device, an organic light-emitting device, etc., but is not limited thereto. Various types of light-emitting devices may be applied.

In general, the light-emitting device may include a first electrode, a second electrode facing the first electrode, an emission layer disposed between the first electrode and the second electrode and formed by inkjet printing the aforementioned QD ink composition, a hole transport layer disposed between the first electrode and the emission layer, and an electron transport layer disposed between the emission layer and the second electrode. If necessary, the light-emitting device may further include at least one of a hole injection layer and an electron injection layer.

In addition, the disclosure provides a display apparatus including the QD ink composition. Here, the display apparatus may include a liquid crystal display (LCD) apparatus, an electroluminescent (EL) display apparatus, a plasma display panel (PDP) apparatus, a field emission display (FED) apparatus, an organic light-emitting device (OLED), or the like, but is not limited thereto.

Hereinafter, the disclosure will be described in more detail through preparation examples and examples. However, preparation examples and examples below are only for illustrating the disclosure, and the scope of the disclosure is not limited thereto.

### Preparation Example 1. Polar Solvent A

Polar solvent A was prepared by mixing propylene glycol (hereinafter referred to as PG), butanol, and propylene glycol monomethyl ether acetate (hereinafter referred to as PGMEA) at a volume ratio of about 1:1:1, with a total volume of 2 ml.

### Preparation Example 2. Polar Solvent B

Polar solvent B was prepared by mixing PG and butanol at a volume ratio of about 1:3.

### Preparation Example 3. Polar Solvent C

Polar solvent C was prepared by mixing PG and PGMEA at a volume ratio of about 1:1.

### Preparation Example 4. Polar Solvent D

Polar solvent D was prepared by mixing PG and hexanol at a volume ratio of about 1:1.

### Preparation Example 5. Polar Solvent E

Polar solvent E was prepared by mixing PG and ethanol at a volume ratio of about 1:3.

### Preparation Example 6. Polar Solvent F

Polar solvent F was prepared by mixing PG and butyl acetate at a volume ratio of about 1:1.

### Preparation Example 7. Polar Solvent G

Polar solvent G was prepared by mixing PG and heptanol at a volume ratio of about 1:1.

### Preparation Example 8. Polar Solvent H

Polar solvent H was prepared by mixing PG and acetone at a volume ratio of about 1:1.

### Example 1. Hydrophilic Solvent-type QD Ink Composition

QDs consisting of a green QD solution dispersed in colloidal form in toluene, indium phosphide (InP) as a material for forming a core, zinc selenide (ZnSe) and zinc sulfide (ZnS) were used as materials for forming a shell, and oleic acid used as a ligand were used in the amount of about 0.025 g.

About 0.025 g of ZnCl₂ (5 wt % in ethanol) was added to the green QD solution dispersed in toluene, and then stirred for about 10 minutes. After the stirring, ethanol was added thereto, followed by centrifugation.

After the centrifugation, the resulting solution was re-dispersed in toluene, and about 0.05 g of mercaptosuccinic acid as a surface modifying ligand was added thereto and stirred for 10 minutes.

Finally, hexane was added thereto, and only the surface-modified QDs were obtained by centrifugation and dispersed in Polar Solvent A.

### Example 2

The QD ink composition was prepared in the same manner as in Example 1, but the surface-modified QDs were dispersed in Polar solvent B.

### Example 3

The QD ink composition was prepared in the same manner as in Example 1, but the surface-modified QDs were dispersed in Polar solvent C.

### Example 4

The QD ink composition was prepared in the same manner as in Example 1, but the surface-modified QDs were dispersed in Polar solvent D.

### Example 5

The QD ink composition was prepared in the same manner as in Example 1, but the surface-modified QDs were dispersed in Polar solvent E.

### Example 6

The QD ink composition was prepared in the same manner as in Example 1, but the surface-modified QDs were dispersed in Polar solvent F.

### Example 7

The QD ink composition was prepared in the same manner as in Example 1, but the surface-modified QDs were dispersed in Polar solvent G.

### Example 8

The QD ink composition was prepared in the same manner as in Example 1, but the surface-modified QDs were dispersed in Polar solvent H.

### Comparative Example

QDs consisting of a green QD solution dispersed in colloidal form in cyclohexylbenzene without undergoing surface modification, indium phosphide (InP) as a material for forming a core, zinc selenide (ZnSe) and zinc sulfide (ZnS) were used as materials for forming a shell, and oleic acid used as a ligand were used.

### Experimental Example 1

### Quantum Efficiency (QE) Evaluation

Using QE 2100 equipment, the QE of the ink compositions prepared in Examples 1 to 8 was measured (at an excitation wavelength of 450 nm) under absorption conditions of about 0.6 to about 0.8.

The results are shown in Table 1.

TABLE 1

| | QE(%) |
|---|---|
| Example 1 | 71 |
| Example 2 | 87 |
| Example 3 | 98 |
| Example 4 | ~100 |
| Example 5 | ~100 |
| Example 6 | 98 |
| Example 7 | ~100 |
| Example 8 | ~100 |

In all examples, the QE was found to be 70% or more, and examples 3 to 8 showed significantly excellent QE of about 98% to about 100%.

### Experimental Example 2. Viscosity Evaluation

Using rheometer (MARS-40) equipment, the viscosity of the prepared ink compositions was measured. Here, the con and plate (CP) measurement method was applied, the temperature was set at about 25° C., and the shear rate was 10 sec⁻¹ (start) to 20 sec⁻¹ (end).

In addition to examples 1 to 8, additional polar solvents were prepared by varying the mixing ratio of each polar solvent, and the mixing ratio and viscosity results are shown in Table 2.

TABLE 2

| | Solvent | Mixing ratio | Viscosity(cps) |
|---|---|---|---|
| Example 1 | PG:Butanol:PGMEA | 1:1:1 | 3.5 |
| Example 2 | PG:Butanol | 1:3 | 4.4 |
| Example 2-a | | 1:2 | 12.5 |
| Example 3 | PG:PGMEA | 1:1 | 6.4 |
| Example 3-a | | 1:2 | 3.5 |
| Example 3-b | | 2:1 | 18.0 |
| Example 4 | PG:Hexanol | 1:1 | 12.4 |
| Example 4-a | | 1:1.85 | 8.7 |
| Example 4-b | | 1:3 | 6.3 |
| Example 5 | PG:Ethanol | 1:3 | 2.1 |
| Example 5-a | | 1:2.33 | 2.8 |
| Example 5-b | | 1:1.85 | 3.2 |
| Example 6 | PG:Butyl acetate | 1:1 | 5.0 |
| Example 7 | PG:Heptanol | 1:1 | 14.8 |
| Example 8 | PG:Acetone | 1:1 | 15.9 |

Since the solvents other than PG had less polarity than PG, the viscosity tended to decrease as the proportion of the mixing ratio increased.

The viscosity of examples shown in Table 2 is within a range of about 2 cps to about 16 cps, and in this regard, the ink compositions of these examples were determined to be suitable for use in inkjet printing.

### Experimental Example 3. Evaluation of Amount of Organic Matters/TGA Analysis

The TGA is a thermal analysis technique that measures changes in mass of a sample according to temperature changes. The temperature at which a rapid change in weight occurs may be interpreted as the decomposition temperature of organic materials, and the weight percentage (wt %) occupied by the organic materials may be numerically confirmed according to the degree of the total weight reduction.

The ink compositions of example 1 (ZC-MSA GQD) and comparative example (Ref GQD) were dried in a vacuum oven for more than 1 hour and powdered, and the amount of organic matters were evaluated by using TGA 550 equipment.

The results are shown in Table 3 and graphs below. Measurement conditions: Mass Flow 240 mL/min. equilibrate 40° C. ramp 10° C./min to 700° C./min

Referring to Table 3 and the first graph, in the QDs prepared in comparative example, only the oleic acid (third peak) that was initially attached to the QDs was observed, and there was a decrease in the weight of the organic matters of about 16%. In this regard, it was determined that about 16.3% of the total weight of the oleic acid was attached to the initial QDs.

In Example 1, there was a decrease in the weight of the organic matters by about 15%, and peaks (1st to 3rd peaks) appeared in three parts. The first peak relates to the oleic acid separated from the QDs by substitution with the ligand, the second peak relates to the ligand newly attached to the surface of the QDs, and the third peak relates to the oleic acid that has not yet been substituted.

The decrease in the weight of the total organic matters of example 1 and the comparative example was almost similar, but the values of the third peak of example 1 and the comparative example were 2.767 and 14.348, respectively, having a difference of about 5.2 times, showing that the ligand substitution on the surface of the QDs in example 1 was well achieved. In addition, referring to the second graph, a rapid decrease in the weight occurred from about 180° C. in example 1, whereas a rapid decrease in the weight occurred from about 400° C. in the comparative example, confirming that the main organic matters also had different combustion points from each other.

### Experimental Example 4. Roughness Evaluation

After cleaning an ITO glass, the prepared ink composition was filmed thereon by using a spin coater (3,500 rpm/20s). After drying, a thin film was thus formed on a hot plate at 70° C. for about 15 minutes, the roughness value of the thin film was measured by using Zygo New View 9000 equipment.

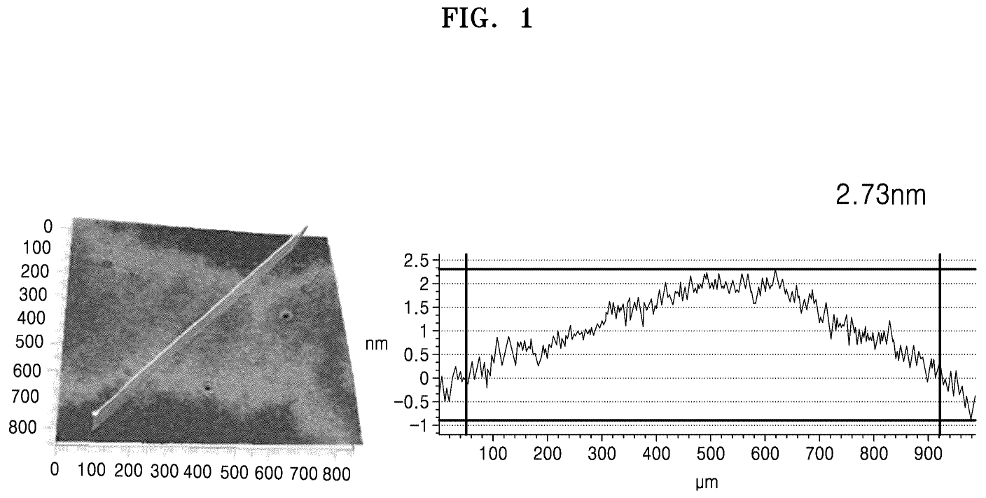

For the roughness evaluation, the ink compositions including the polar solvent shown in Table 4 were used, and the results are shown in FIGS. 1 to 3.

TABLE 4

| | Solvent | Mixing ratio |
|---|---|---|
| Example 4 | PG:Hexanol | 1:1 |
| Example 4-a | | 1:1.85 |
| Example 4-b | | 1:3 |

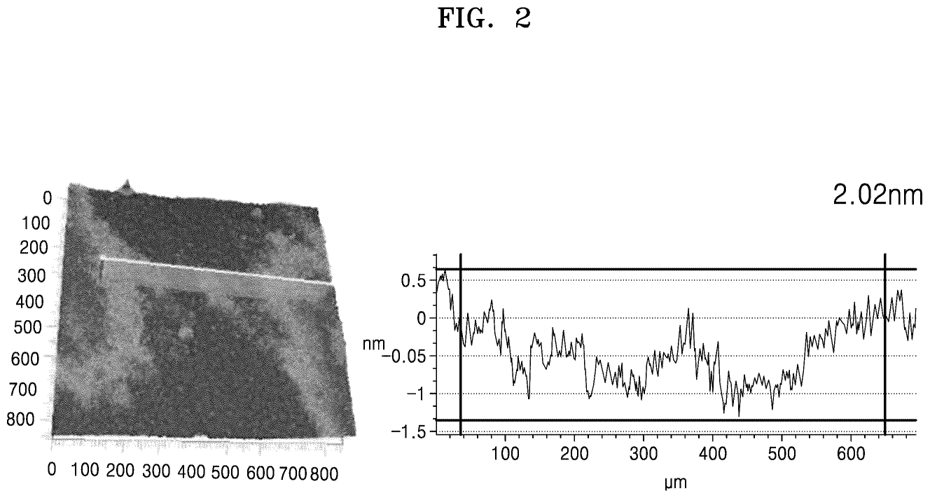

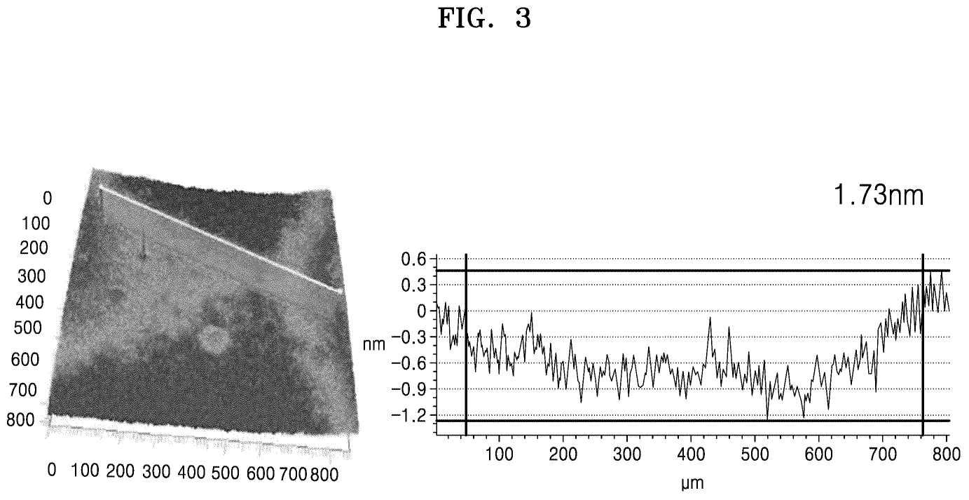

Referring to FIGS. 1 to 3, the roughness value at the thickest part of an arbitrary cross section of each thin film was measured and marked. Each of the right graphs in FIGS. 1 to 3 represents the height of the thin film. Also, the roughness value is the average height deviation value of the thin film. The maximum roughness value of the thin film was measured to be about 2.73 nm in Example 4 (FIG. 1), about 2.02 nm in Example 4-a (FIG. 2), and about 1.73 nm in Example 4-b (FIG. 3).

Accordingly, it was confirmed that, depending on the mixing ratio of the polar solvent, the roughness value of the ink composition could be evenly adjusted.

### Experimental Example 5. Ejectability Evaluation

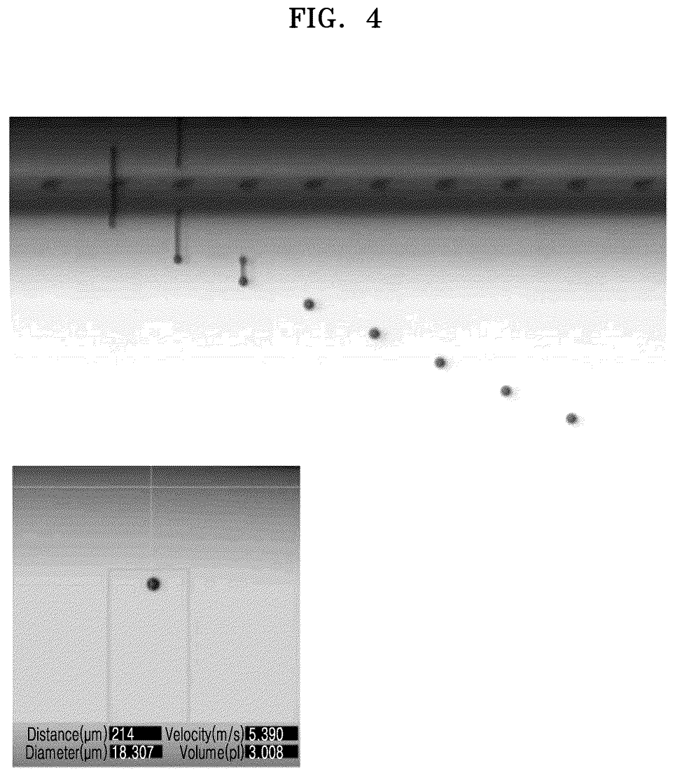

Using Omnijet 200 equipment after installation on the mounting Fuji Film Dimatix 2.4pl head (DMC-11610), the ejectability evaluation was performed. Here, the ink composition of example 1 was used and ejected in the form of 1 drop. Photographs were taken in a time-sharing manner according to the time at which 1 drop of ink was ejected, and the results are shown in FIG. 4.

Referring to FIG. 4, a tail (i.e. straight-lined shape) was formed in the ink at the beginning of ejection, but it was confirmed that the ink was gradually ejected in a balanced spherical shape. Here, the diameter of the sphere was about 18.307 μm.

### Experimental Example 6. Evaluation of Inkjet Shape (Based on CRF)

Similar to experimental example 5, the ink composition of example 1 was ejected by using Omnijet 200 equipment after installed on Fuji Film Dimatix 2.4pl head (DMC-11610), and the ejection pattern was evaluated.

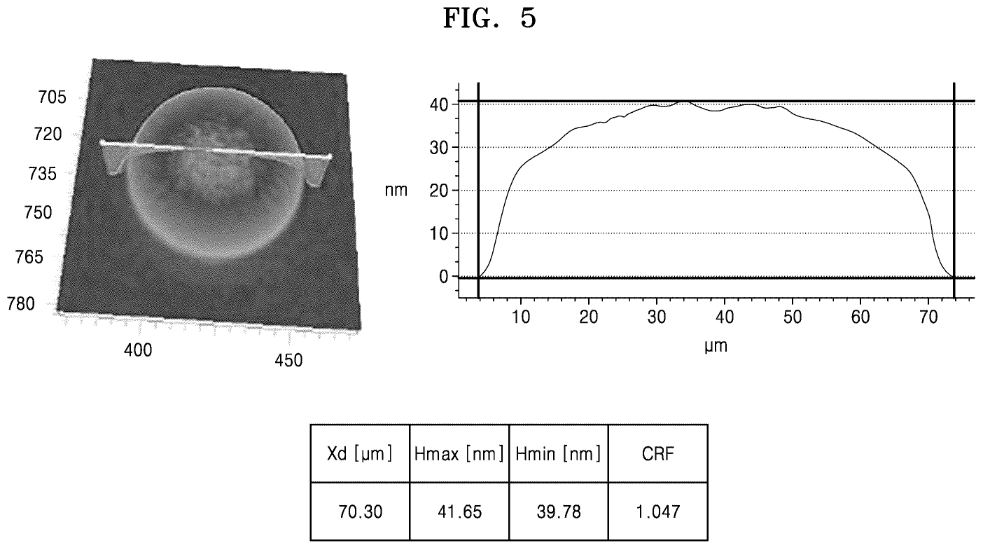

When evaluating the pattern, an ITO glass was used as a bottom substrate, and the size and height of the pattern formed on the substrate were measured by using Zygo New View 9000 equipment. Here, to quantify the degree of the coffee-ring effect, Equation 1 was introduced, and the results are shown in FIG. 5.

Coffee-ring factor (CRF)=Hmax/Hmin [Equation 1]

In Equation 1, Hmax refers to the greatest thickness of the pattern, Hmin refers to the smallest thickness of a pattern, and the CRF value refers to the degree of the coffee-ring effect. That is, the CRF value of 1 indicates that the coffee-ring effect has been completely removed.

Referring to FIG. 5, the inkjet shape in Example 1 had Hmax of about 41.62 nm and Hmin of about 39.78 nm (not shown). In this regard, the CRF was about 1.047, which is very close to 1, and thus it is determined that the coffee-ring effect had little effect. Even by referring to the three-dimensional shape, it was confirmed that the inkjet shape was even overall, not just in one cross section.

According to an embodiment of the disclosure, QDs may be dispersed in a polar solvent through surface modification, and accordingly, may have properties (e.g., viscosity, etc.) suitable for use in inkjet printing.

A solvent-type QD ink composition may be prepared by using a polar solvent, and thus may have or exhibit an easily adjusted viscosity.

In addition, an emission layer is prepared by using a hydrophilic solvent-type ink composition according to the disclosure, the emission layer does not have etching problems although a non-polar solvent-type electron transport layer is formed on the emission layer.

Accordingly, the polar solvent-type ink composition of the disclosure may be usefully applied in the manufacture of light-emitting devices, such as self-emissive displays, through an inkjet printing process. Furthermore, the polar solvent-type ink composition may also exhibit a more advantageous effect in commercialization and large-scale production through the application of a simple and inexpensive inkjet process.

The effects according to the disclosure are not limited to the contents exemplified above, and more diverse effects are included in the present specification.

It is obvious to those skilled in the art that the disclosure is not limited to Examples above, and that various modifications or variations may be implemented without departing from the technical gist of the disclosure.

What is claimed is:

1. A hydrophilic quantum dot, wherein the hydrophilic quantum dot is surface-modified by a ligand comprising:
a reactive group capable of binding to a surface of the quantum dot; and
an organic group having hydrophilicity.

2. The hydrophilic quantum dot of claim 1, wherein the hydrophilic quantum dot is suitable for inkjet printing.

3. The hydrophilic quantum dot of claim 1, wherein the reactive group is selected from the group consisting of COOH, CN, NH₂, NH, N, SH, PO, P, OH, COOR′, —C(═O)—, PO(OH)₂ and POOH.

4. The hydrophilic quantum dot of claim 1, wherein the organic group is an organic group having 3 to 10 carbon atoms.

5. The hydrophilic quantum dot of claim 4, wherein the organic group comprises at least one element selected from the group consisting of nitrogen (N), oxygen (O) and sulfur (S).

6. The hydrophilic quantum dot of claim 1, wherein the ligand is mercaptosuccinic acid.

7. The hydrophilic quantum dot of claim 1, wherein the surface of the quantum dot comprises one of Mg, Ca, Sc, Ti, V, Cr, Mn, Fe, Co, Ni, Cu, Zn, Ga, Ge, Sr, Y, Zr, Nb, Mo, Tc, Ru, Rh, Pd, Cd, In and Sn.

8. A quantum dot ink composition, comprising:
quantum dots surface-modified by a ligand; and
a polar solvent,
wherein the polar solvent comprises two or more types.

9. The quantum dot ink composition of claim 8, wherein the polar solvent comprises propylene glycol.

10. The quantum dot ink composition of claim 9, wherein the polar solvent further comprises one or more functional groups selected from the group comprising carboxy groups, hydroxy groups, sulfur groups, ester groups and ketone groups.

11. The quantum dot ink composition of claim 9, wherein a total volume ratio of the propylene glycol to other solvents in the polar solvent is in a range of about 1:0.5 to about 1:5.

12. The quantum dot ink composition of claim 8, wherein the quantum dot ink composition has a viscosity in a range of about 2 centipoise (cps) to about 20 cps.

13. The quantum dot ink composition of claim 8, wherein the quantum dot ink composition has a roughness in a range of about 0.5 nm to about 5 nm.

14. The quantum dot ink composition of claim 8, wherein the quantum dots are dispersible in the polar solvent.

15. The quantum dot ink composition of claim 8, wherein the quantum dot ink composition is for inkjet printing.

16. The quantum dot ink composition of claim 8, wherein the quantum dot ink composition has quantum efficiency (QE) of 70% or more.

17. A light-emitting device comprising an emission layer prepared by using the quantum dot ink composition of claim 8.

18. A display apparatus comprising the light-emitting device of claim 17.
